(19) United States
(12) Patent Application Publication
(10) Pub. No.: US 2026/0299789 A1
(43) Pub. Date: Oct. 1, 2026

(54) MEMORY SYSTEMS, METHODS OF OPERATING MEMORY SYSTEMS, MEMORY CONTROLLERS AND MEMORY DEVICES

(71) Applicant: Yangtze Memory Technologies Co., Ltd., Hubei (CN)

(72) Inventor: Tao Xiong, Hubei (CN)

(21) Appl. No.: 19/236,286

(22) Filed: Jun. 12, 2025

(30) Foreign Application Priority Data
Jan. 24, 2025 (CN) 202510121504.7

(51) Int. Cl. G06F 3/06

(52) U.S. Cl. CPC G06F 3/0613; G06F 3/0659; G06F 3/0679

(57) ABSTRACT

An example memory system includes a memory controller and a memory device coupled to the memory controller. The memory device includes multiple dies, each die includes multiple planes, and each of the planes includes multiple physical blocks. The memory controller is configured to: receive a first write request; and send a first write command to the memory device in response to the first write request. The first write command includes physical addresses of first physical blocks, and the number of the first physical blocks is less than the total number of planes in the multiple dies. The memory device is configured to: perform a program operation on the first physical blocks in response to the first write command.

### CROSS-REFERENCE TO RELATED APPLICATION

This application claims priority to and the benefit of Chinese Patent Application 202510121504.7, filed on Jan. 24, 2025, which is hereby incorporated by reference in its entirety.

### TECHNICAL FIELD

The present disclosure relates to the field of semiconductor chip technology, and particularly to memory systems, methods of operating the memory systems, memory controllers, and memory devices.

### BACKGROUND

NAND memory devices have characteristics such as data nonvolatility, fast read and write speeds, low power consumption, and long service life, etc., and are widely employed in various electronic products, such as mobile phones, computers, smart sensors, positioning devices, etc.

### BRIEF DESCRIPTION OF THE DRAWINGS

In order to more clearly illustrate the technical solution in this disclosure, a brief introduction will be given to the drawings required for some examples of the present disclosure. It is apparent that the drawings described below are only drawings of some examples of the present disclosure. For those skilled in the art, other drawings may be obtained based on these drawings. In addition, the accompanying drawings in the following description may be regarded as schematic diagrams and are not limitations on the actual size of products, the actual process of methods, the actual timing of signals and the like involved in examples of the present disclosure.

FIG. 1 is a structure diagram of a memory system provided in an example of the present disclosure.

FIG. 2 is a structure diagram of physical blocks provided in an example of the present disclosure.

FIG. 3 is a partial cross-sectional schematic diagram of a memory string provided in an example of the present disclosure.

FIG. 4 is a schematic diagram of the partitioning of a super physical block provided in an example of the present disclosure.

FIG. 5 is a schematic diagram of threshold voltage distribution intervals of memory cells in various memory modes provided in an example of the present disclosure.

FIG. 6 is a flowchart of an operation method of a memory system provided in an example of the present disclosure.

FIG. 7 is a structure diagram of physical addresses of physical blocks provided in an example of the present disclosure.

FIG. 8 is a schematic diagram of physical addresses of physical blocks before and after a swap table mapping provided in an example of the present disclosure.

FIG. 9 is a schematic diagram of physical addresses of physical blocks before and after another swap table mapping provided in an example of the present disclosure.

FIG. 10 is a schematic diagram of physical addresses of physical blocks in various super physical blocks of a device provided by an example of the present disclosure.

FIG. 11 is a schematic diagram of physical addresses of physical blocks of various super physical blocks determined by the mapping of a first mapping function (offset parameter BLK_shift=7) provided in an example of the present disclosure.

FIG. 12 is a schematic diagram of physical addresses of physical blocks of various super physical blocks determined by the mapping of a first mapping function (offset parameter BLK_shift=6) provided in an example of the present disclosure.

FIG. 13 is a structure diagram of a memory controller provided in an example of the present disclosure.

FIG. 14 is a structure diagram of a memory device provided in an example of the present disclosure.

FIG. 15 is a schematic diagram of a connection structure between a peripheral circuit and a memory array provided in an example of the present disclosure.

Reference numbers: 100 Memory system; 110 Memory controller; 120 Memory device; 200 Physical block; 210 Memory string; 211 Top select transistor; 212 Memory cell; 213 Bottom select transistor; 310 Semiconductor layer; 320 Stacked structure; 321 Gate conductive layer; 322 Dielectric layer; 410 Bit line; 420 Source line; 430 Top select line; 440 Word line; 450 Bottom select line; 510 Processing circuit; 520 First interface circuit; 530 Second interface circuit; 610 Peripheral circuit; 611 Control logic circuit; 612 I/O interface; 613 Voltage generator; 614 Column decoder; 615 Line decoder; 616 Page buffer; 617 Data bus; 618 Register; 620 Memory array.

### DETAILED DESCRIPTION

Technical solutions in some examples of the present disclosure will be described clearly and completely in conjunction with the accompanying drawings below. The described examples are only a part of, not all of the examples of the present disclosure. Based on the examples provided in the present disclosure, all other examples obtained by those skilled in the art are within the scope of the present disclosure.

Unless otherwise required by the context, the term “include” shall be interpreted throughout the specification and claims as open and inclusive, meaning “including, but not limited to”. In the description of the specification, terms “one example”, “some examples”, or “some examples” and the like are intended to indicate that specific features, structures, materials or characteristics related to the implementation or example are included in at least one implementation or example of the present disclosure. The schematic representation of the above terms does not necessarily refer to the same implementation or example. In addition, the specific features, structures, materials, or characteristics described may be included in any one or more implementations or examples in any appropriate manner.

The terms “first” and “second” below are only for descriptive purposes and should not be understood as indicating or implying relative importance or implying the number of technical features indicated. Thus, the features limited with “first” and “second” may explicitly or implicitly include one or more of these features. In the description of examples of the present disclosure, the meaning of “multiple” refers to two or more, unless otherwise specified.

When describing some examples, expressions such as “coupling” and “connection” and their derivatives may be used. For example, in describing some examples, the term “connection” may be used to indicate that two or more components have direct physical or electrical contact with each other. For another example, in describing some examples, the term “coupling” may be used to indicate that two or more components have direct physical or electrical contact. However, the term “coupling” may also refer to two or more components that do not have direct contact with each other but still cooperate or interact with each other. Examples disclosed here are not necessarily limited to the content herein.

The use of “applicable” or “configured to” herein implies an open and inclusive language, which does not exclude devices that are applicable or configured to perform additional tasks or operations.

In addition, the use of “based on” implies openness and inclusiveness, as processes, steps, calculations, or other actions “based on” one or more of the conditions or values described may be based on additional conditions or values beyond those described in practice.

When a memory device adopts multi-step program operations, the memory controller that controls the memory device needs a write buffer with a large cache capacity to cache data to be written, and the memory controller needs a built-in capacitor with a large capacitance to perform power loss protection (PLP) functions.

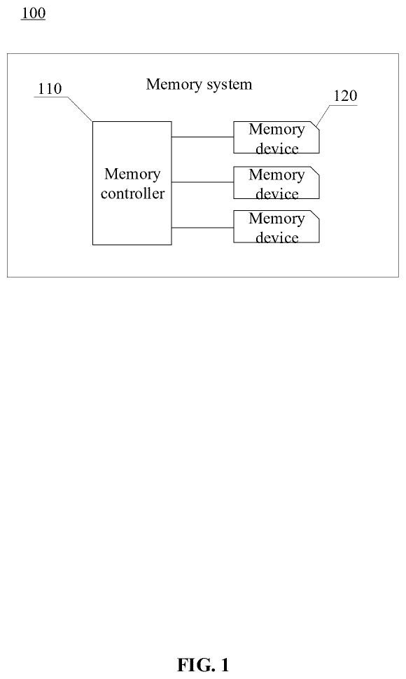

Some examples of the present disclosure provide a memory system. As shown in FIG. 1, the memory system 100 includes a memory controller 110 and a memory device 120, with the memory controller 110 coupled to the memory device 120. In some implementations, the memory controller 110 may be configured to manage data stored in the memory device 120 and communicate with external devices such as a host. In some implementations, the memory controller 110 may also be configured to control operations of the memory device 120, such as read, erase, and program operations. In some implementations, the memory controller 110 may also be configured to manage various functions related to data stored or to be stored in the memory device 120, including at least one of bad block management, garbage collection, logical to physical address translation, and wear leveling. In some examples, the memory controller 110 is further configured to process error correction codes for data read from or written to the memory device 120.

Of course, the memory controller 110 may also perform any other suitable functions. For example, the memory controller 110 formats the memory device 120. For example, the memory controller 110 may also communicate with external devices through at least one of various interface protocols. It should be noted that an interface protocol may be at least one of a universal serial bus (USB) protocol, a multimedia card (MMC) protocol, a peripheral component interconnect (PCI) protocol, a PCI express (PCI-E) protocol, an advanced technology attachment (ATA) protocol, a serial ATA protocol, a parallel ATA protocol, a small computer system interface (SCSI) protocol, an enhanced small disk interface (ESDI) protocol, an integrated drive electronics (IDE) protocol.

In some implementations, the memory system 100 may be packaged as different types of electronic products. For example, the memory system 100 includes a controller and a memory device 120, and the memory system 100 may be integrated into a memory card. The memory card includes any one of a personal computer memory card international association (PCMCIA card), a compact flash (CF) card, a smart media (SM) card, a memory stick, a multimedia card (MMC), and a secure digital (SD) card. For example, the memory system 100 includes a controller and multiple memory devices 120, and is integrated into a solid state drive (SSD).

In some implementations, the memory system 100 may be applied to different types of electronic devices, such as mobile phones (e.g., cell phones), desktop computers, tablets, laptops, servers, on-board devices, game consoles, printers, positioning devices, wearable devices, smart sensors, power banks, virtual reality (VR) devices, augmented reality (AR) devices, and servers, and any other electronic device that may store data.

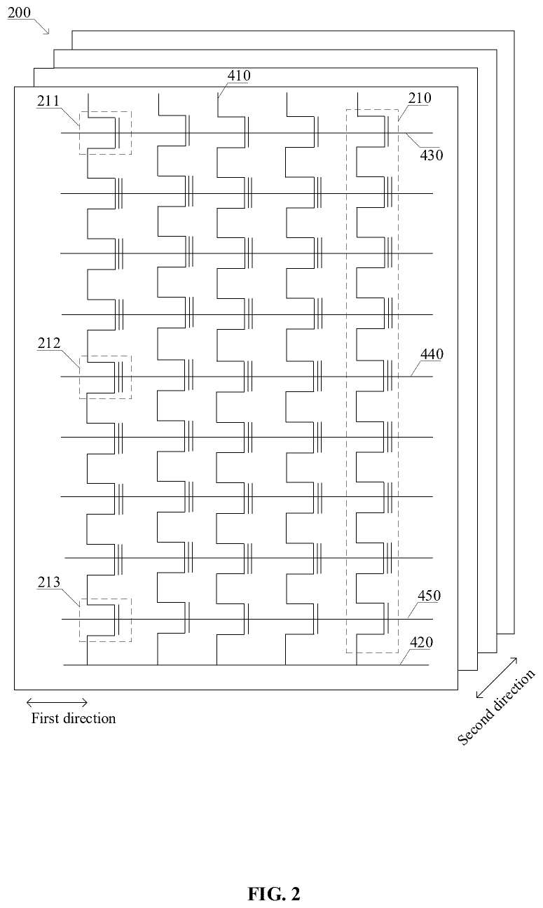

In some implementations, the memory device 120 includes multiple dies, each of the dies comprises multiple planes, and each of the planes includes multiple physical blocks 200. As shown in FIG. 2, each physical block 200 may include multiple memory strings 210, with one end of the memory string 210 coupled to a bit line (BL) 410 and the other end coupled to a source line (SL) 420. Each memory string 210 may include a top select gate (TSG) 211, multiple memory cells 212, and a bottom select gate (BSG) 213 stacked sequentially in series. In some implementations, the memory cell 212 may be a device capable of storing charges, such as a floating gate transistor or a charge trap field-effect transistor.

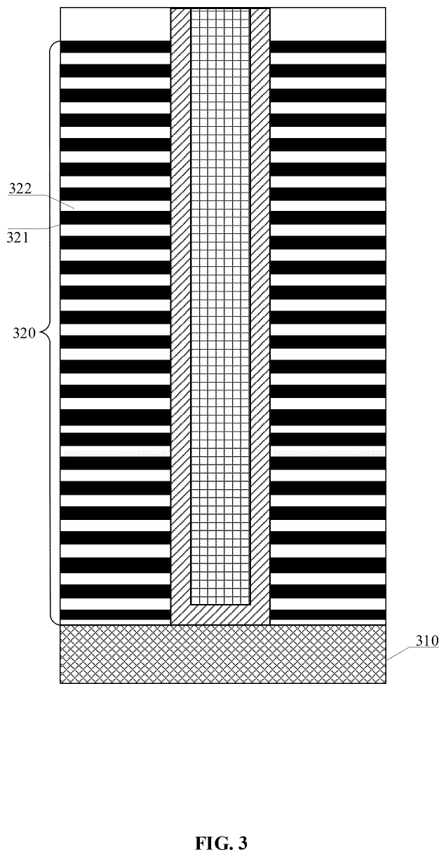

FIG. 3 shows a partial cross-sectional schematic diagram of a an example memory string 210. The memory string 210 may extend vertically above the semiconductor layer 310. The semiconductor layer 310 may include silicon (e.g., monocrystalline silicon), silicon germanium (SiGe), gallium arsenide (GaAs), germanium (Ge), silicon on insulator (SOI), germanium on insulator (GOI), or any other suitable material.

The memory string 210 may include a channel structure that runs through the stacked structure 320, which may include alternating gate conductive layers 321 and dielectric layers 322. The number of the gate conductive layers 321 and dielectric layers 322 in the stacked structure 320 is correlated with the number of the memory cells 212 in the memory string 210.

The gate conductive layer 321 may include conductive materials, including but not limited to tungsten (W), cobalt (Co), copper (Cu), aluminum (Al), polycrystalline silicon, doped silicon, silicide, or any combination thereof. In some implementations, each gate conductive layer 321 includes a metal layer, such as a tungsten layer. In some implementations, each gate conductive layer 321 includes a doped polycrystalline silicon layer. Each gate conductive layer 321 may include a control gate surrounding the memory cell 212, and the gate conductive layer 321 at the top of the stacked structure 320 may extend laterally and be coupled to a top select line (TSL) 430, the gate conductive layer 321 at the bottom of the stacked structure 320 may extend laterally and be coupled to a bottom select line (BSL) 450, or the gate conductive layer 321 between the top select line 430 and the bottom select line 450 may extend laterally and be coupled to a word line (WL) 440.

It should be understood that although not shown in FIG. 3, additional components for the memory string 210 may be formed, including but not limited to gate line gaps/source contacts, local contacts, interconnect layers, etc.

Please continue to refer to FIG. 2. The memory string 210 may be arranged in a row along a first direction, and multiple rows of memory strings 210 may be arranged as a physical block 200 along a second direction perpendicular to the first direction. In some examples, in the same row of memory strings 210, the gate of the top select transistor 211 of each memory string 210 may be coupled to the same top select line 430. In some examples, the gate of the top select transistor 211 of a portion of the rows of memory strings 210 in multiple rows of memory strings 210 may be coupled to the same top select line 430. The gate of the top select transistor 211 coupled to the memory string 210 of the same top select line 430 may constitute a memory chip. The gate of the bottom select transistor 213 in each memory string 210 may be coupled to the same bottom select line 450. In some implementations, the selected memory string 210 may be activated during read, program, and erase operations through the top selection line 430 and the bottom selection line 450.

Each memory string 210 is coupled to the peripheral circuit 610 through a corresponding bit line 410, for example, the drain of the top select transistor 211 in the memory string 210 is coupled to the bit line 410. In order to reduce the number of the bit lines 410, the memory string 210 in any memory chip may be coupled to the same bit line 410 as the memory string 210 at the corresponding position in other memory chips.

For multiple memory strings 210 in physical block 200, the control gate of memory cell 212 in any memory string 210 may be coupled to the same word line 440 as the control gate of memory cell 212 at the corresponding position in other memory strings 210. The source of the bottom select transistor 213 in the memory string 210 may be coupled to the source line 420 (or, a common source line (CSL)).

It should be noted that the accompanying drawings of the present disclosure illustrate example structures of physical block 200 in some examples, but in practice, the structure of physical block 200 may also be implemented in other ways.

In some implementations, multiple physical blocks 200 located on different planes may constitute a super physical block (SPB). That is to say, the number of the physical blocks 200 included in a single super physical block is equal to the total number of the planes included in multiple dies.

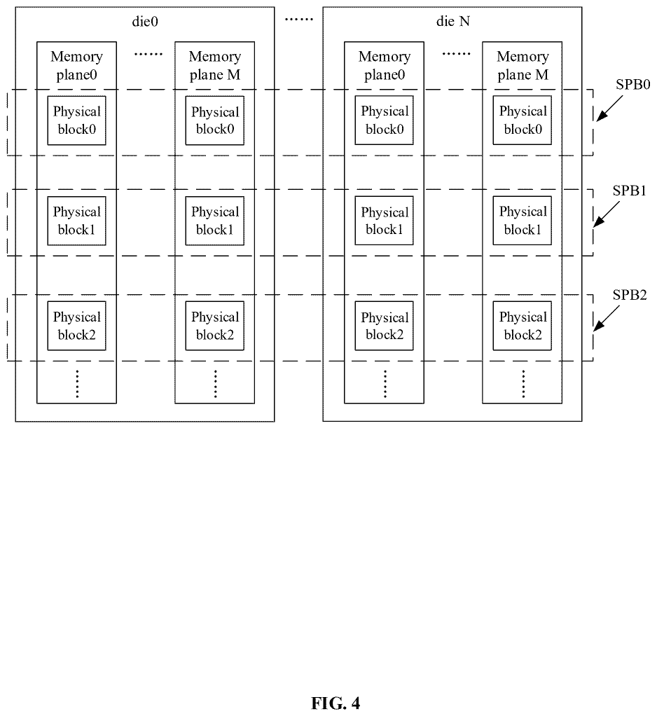

In some implementations, each die may include an equal number of planes. For example, as shown in FIG. 4, the memory device 120 includes die 0 to die N, each die including plane 0 to plane M, and each plane including multiple physical blocks with different block addresses such as block 0, block 1, block 2, etc. The total number of the planes included in multiple dies is equal to the number of the dies multiplied by the number of the planes included in a single die. That is to say, the memory device 120 includes multiple physical blocks block0, block1, and block2 located on different planes, wherein the number of the physical blocks block0, block1, and block2 are equal, all equal to the number of dies multiplied by the number of planes included in a single die (e.g., N× M).

Please continue to refer to FIG. 4. Multiple physical blocks block0 may constitute a super physical block SPB0, multiple physical blocks block1 may constitute a super physical block SPB1, and multiple physical blocks Block2 may constitute a super physical block SPB2. In some implementations, the memory controller 110 may control the memory device 120 to perform parallel operations on multiple physical blocks 200 in a super physical block responsive to a received write request, so as to improve the read speed or programming speed of the memory device 120.

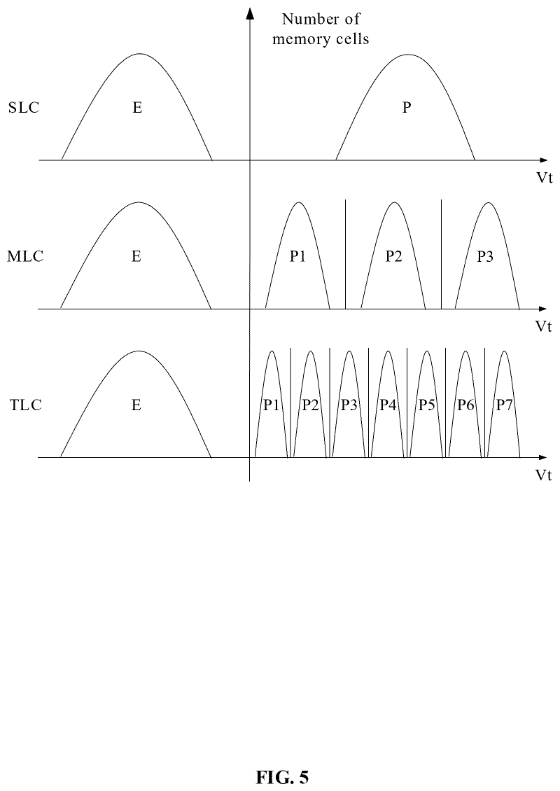

In some implementations, the memory mode of each memory cell 212 in physical block 200 may include a single-level cell (SLC) and a multi-level cell (MLC). As shown in FIG. 5, the memory cell 212 using a single-level cell memory mode may store one bit (e.g., 1 bit) and may have two states, e.g., an erase (E) state and a program (P) state. The memory cell 212 using a multi-level cell memory mode may store two bits (e.g., 2 bits) or more, and may have four or more states. In some examples, memory cell 212 may adopt a two-level cell memory mode, wherein each memory cell 212 may store two bits and may have four states, e.g., three program states (e.g., P1 state, P2 state, and P3 state in FIG. 5) and one erase state (e.g., E state in FIG. 5). In some examples, memory cell 212 may also adopt a three-level cell (TLC) memory mode, wherein each memory cell 212 may store three bits and may have eight states, e.g., seven program states (e.g., P1 state, P2 state, P3 state, P4 state, P5 state, P6 state, and P7 state in FIG. 5) and one erase state (e.g., E state in FIG. 5). In some examples, memory cell 212 may also adopt a quad-level cell (QLC) memory mode, wherein each memory cell 212 may store four bits and may have sixteen states, e.g., fifteen program states (e.g., P1-P15 states in FIG. 5) and one erase state (e.g., E state in FIG. 5). In some implementations, each state of memory cell 212 has a corresponding threshold voltage distribution interval.

As shown in FIG. 5, as the number of the storage bits in each memory cell 212 increases, the threshold voltage distribution interval corresponding to each program state gradually becomes narrow. As the threshold voltage distribution interval of memory cell 212 gradually becomes narrow, the memory device 120 needs to optimize programming performance to ensure that the threshold voltage of memory cell 212 may be accurately set to a desired threshold voltage distribution interval. In some implementations, the memory device 120 may employ multi-step program operations to optimize programming performance, wherein the multi-step program operation includes at least a first program operation and a second program operation. The first program operation is configured to roughly set the threshold voltage of the memory cell 212, and the second program operation is configured to accurately set the threshold voltage of the memory cell 212. In some examples, the memory device 120 first performs a first program operation on the memory cell 212 coupled to the word line WLn, and then performs a second program operation on the memory cell 212 coupled to the word line WLn at least after performing a first program operation on the memory cell 212 coupled to the word line WLn+1.

After performing the second program operation on the memory cell 212 coupled to the word line WLn is completed, the data cached in the memory controller 110 that needs to be written to the memory cell 212 coupled to the word line WLn may be released, so that the memory controller 110 requires to cache a larger amount of data. As a result, on the one hand, the memory controller 110 requires a write buffer with a larger cache capacity to cache data that is to be written to the memory device 120, and on the other hand, the memory controller 110 requires capacitors with a larger built-in capacitance to perform power loss protection functions. These built-in capacitors charge during normal operations and may provide a brief power supply when the power is off, ensuring that the memory system 100 has enough time to safely write the cached data in the write buffer to the memory device 120. A write buffer with larger cache capacity have larger volumes to cache more data and capacitors with larger capacitance have larger volumes to store more charge, which easily makes the design of a circuit board more difficult.

In order to reduce the demand for write buffers and built-in capacitors by the memory controller 110, a first write request is received and a first write command is sent to the memory device in response to the first write request. The first write command includes physical addresses of the first physical blocks, and the number of the first physical blocks is less than the total number of the planes in multiple dies. The memory device is configured to perform program operations on the first physical blocks in response to the first write command. As a result, the amount of written data each time performing parallel data writing in an implementation of the present disclosure is reduced, which significantly reduces the demand for write buffers by the memory controller 110, and thus reduces the demand for built-in capacitors for performing power loss protection functions, thereby reducing the design difficulty of the circuit board.

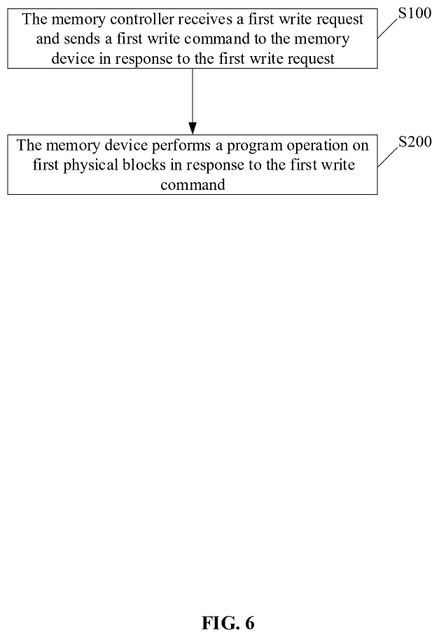

Implementations of the present disclosure further provide an operation method of the memory system 100. As shown in FIG. 6, the operation method includes S100-S200, as follows:

S100: The memory controller receives a first write request and sends a first write command to the memory device in response to the first write request.

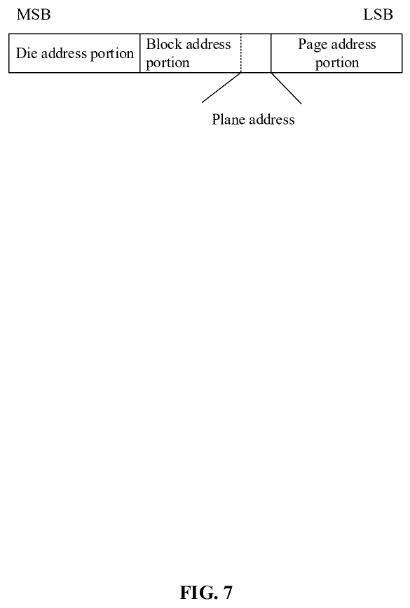

In some implementations, the memory controller 110 may determine a super physical block in response to a write request sent by a host. For example, the memory controller 110 may determine the super physical block SPB0 in response to the first write request. In some implementations, the super physical block SPB0 includes first physical blocks and third physical blocks, and the sum of the number of the first physical blocks and the number of the third physical blocks comprise the total number of the planes included in the multiple dies in the memory device 120. As shown in FIG. 7, the physical address may include a die address portion, a block address portion, and a page address portion, wherein the die address portion is at the most significant bit (MSB), the page address portion is at the least significant bit (LSB), and the least significant bit in the block address is the plane address. In examples of the present disclosure, the physical address includes at least a die address portion and a block address portion, and the block addresses in the physical addresses of the first physical blocks are the same as the block addresses in the physical addresses of the third physical blocks.

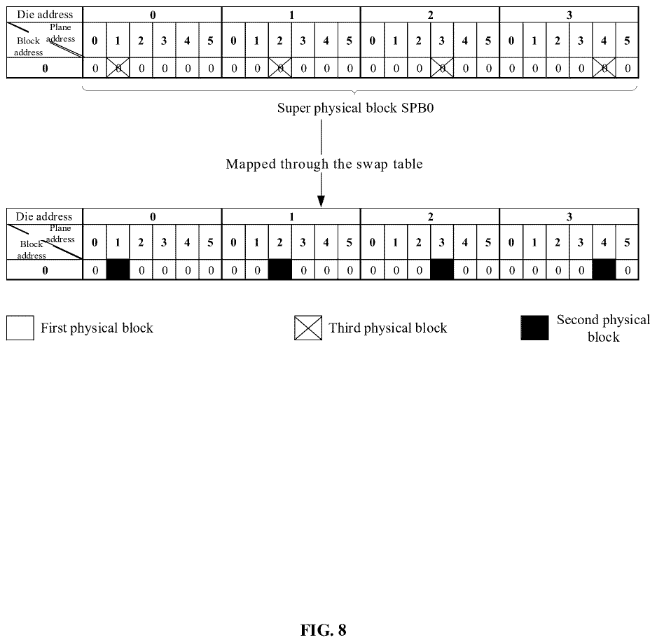

The memory controller 110 is configured with a swap table, and the swap table includes the mapping relationship between the third physical blocks and the second physical blocks. As shown in FIG. 8, the memory controller 110 may determine the physical addresses of the second physical blocks based on the swap table and the physical addresses of the third physical blocks, that is, swap the third physical blocks into the second physical blocks, thereby determining the first physical blocks and the second physical blocks. After swapping, the sum of a number of the first physical blocks and a number of the second physical blocks is also equal to the total number of the planes in multiple dies.

The second physical blocks comprise bad blocks. After the memory controller 110 swaps the third physical blocks for the second physical blocks, the first write command sent to the memory device 120 skips the physical addresses of the second physical blocks (e.g., does not include the physical addresses of the second physical blocks) and only includes the physical addresses of the first physical blocks, so that the number of the first physical blocks is less than the total number of the planes in multiple dies. Moreover, since the memory controller 110 does not swap the first physical blocks with other physical blocks 200, block addresses in the physical addresses of the first physical blocks are the same.

In some implementations, the bad blocks include physical blocks 200 marked as bad blocks by the memory controller 110. The memory controller 110 creates a bad block table (BBT) to record information on factory bad blocks that initially have defects during the manufacturing process and grown bad blocks that become defective after multiple programming and erase cycles. When the memory controller 110 needs to control the memory device 120 to perform data write or read operations, it will avoid the physical blocks 200 marked as bad blocks based on the bad block table to ensure the normal storage and reading of data, thereby ensuring the accuracy and integrity of data.

In the early stages of employing of memory system 100, the number of the grown bad blocks is relatively small, resulting in a small number of physical blocks 200 marked as bad blocks by memory controller 110, which makes it difficult to meet the requirement of swapping the third physical blocks for the second physical blocks. Therefore, in some implementations, the physical blocks 200 that store system data may also serve as bad blocks. It should be understood that the physical blocks 200 storing system data are not real bad blocks, but are physical blocks 200 configured to store system data, or physical blocks 200 reserved to be configured to store system data.

In some implementations, the bad blocks may also include virtual bad blocks configured by the memory controller 110, and the number of the virtual bad blocks is determined based on the number of the multiple physical blocks 200 included in each plane and a virtual bad block ratio. The virtual bad block ratio may be determined based on an expected buffer capacity of a write buffer.

As the memory system 100 is employed, the number of the grown bad blocks gradually increases, so that the physical blocks 200 marked as bad blocks by the memory controller 110 may already meet the requirement of swapping the third physical blocks for the second physical blocks. At this point, the memory controller 110 may not need to configure virtual bad blocks or treat the physical blocks 200 that store system data as bad blocks.

In some other examples, a super physical block SPB0 includes third physical blocks and fourth physical blocks. The sum of the number of the third physical blocks and the number of the fourth physical blocks comprise the total number of the planes included in multiple dies in the memory device 120, and the block addresses in the physical addresses of the third physical blocks are the same as the block addresses in the physical addresses of the fourth physical blocks.

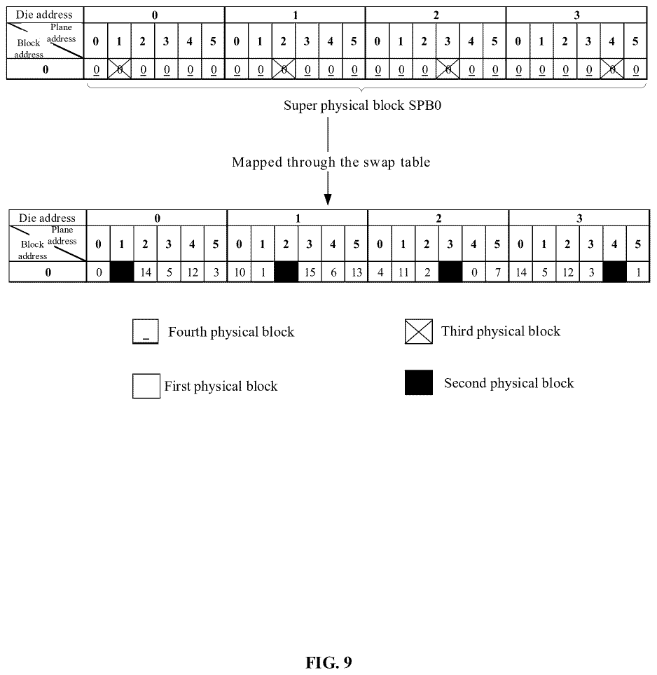

The memory controller 110 is configured with a swap table, and the swap table includes a mapping relationship between the third physical blocks and the second physical blocks, and a mapping relationship between the fourth physical blocks and the first physical blocks. As shown in FIG. 9, the memory controller 110 may determine the physical addresses of the second physical blocks based on the swap table and the physical addresses of the third physical blocks, that is, swap the third physical blocks into the second physical blocks. The memory controller 110 may also determine the physical addresses of the first physical blocks based on the swap table and the physical addresses of the fourth physical blocks, that is, swap the fourth physical blocks into the first physical blocks, thereby determining the first physical blocks and the second physical blocks. After swapping, the sum of a number of the first physical blocks and a number of the second physical blocks is also equal to the total number of the planes in multiple dies.

After the memory controller 110 swaps the third physical blocks for the second physical blocks and swaps the fourth physical blocks for the first physical blocks, the first write command sent to the memory device 120 skips the physical addresses of the second physical blocks (e.g., does not include the physical addresses of the second physical blocks) and only includes the physical addresses of the first physical blocks, so that the number of the first physical blocks is less than the total number of the planes in multiple dies. Moreover, since the first physical blocks are determined by the memory controller 110 through swapping the fourth physical blocks, at least one block address in the physical addresses of the first physical blocks is different from the block addresses in the physical addresses of other first physical blocks.

In some implementations, the memory controller 110 may also achieve a bidirectional mapping between the third physical blocks and the second physical blocks, and a bidirectional mapping between the fourth physical blocks and the first physical blocks, through a mapping function.

Implementations of the present provide a first mapping function for implementing the mapping from the third physical blocks to the second physical blocks and from the fourth physical blocks to the first physical blocks.

The input parameters of the first mapping function include (n_die, n_plane, n_block), and the output parameters include (N_die, N_plane, N_block), wherein n_die is the die address in the physical addresses of the third physical blocks (or the fourth physical blocks), n_plane is the plane address in the physical addresses of the third physical blocks (or the fourth physical blocks), and n_block is the block address in the physical addresses of the third physical blocks (or the fourth physical blocks). N_die is the die address in the physical addresses of the second physical blocks (or the first physical blocks), N_plane is the plane address in the physical addresses of the second physical blocks (or the first physical blocks), and N_block is the block address in the physical addresses of the second physical blocks (or the first physical blocks).

In some examples, the first mapping function includes:

$$N\_die = n\_die ;$$

That is to say, the die addresses in the physical addresses of the second physical blocks (or the first physical blocks) are the same as the die addresses in the corresponding physical addresses of the third physical blocks (or the fourth physical blocks).

In some examples, the first mapping function also includes:

$$N\_plane = n\_plane ;$$

That is to say, the plane addresses in the physical addresses of the second physical blocks (or the first physical blocks) are the same as the plane addresses in the corresponding physical addresses of the third physical blocks (or the fourth physical blocks).

In some examples, the first mapping function also includes:

N_block=(n_block+(n_die×plane_cnt+n_plane)×BLK_shift) % block_cnt;

Wherein plane_cnt is a number of planes in a single die, BLK_shift is an offset parameter, and block_cnt is determined by a number of the good blocks in a single plane and the expected bad block ratio. For example, if a single plane contains an average of 13 good blocks and the expected bad block ratio is 20%, then the memory controller 110 may expand 3 (13×20%=2.6; can only be more, rounded up) bad blocks in each plane, block_cnt=13+3=16, wherein the bad blocks may be the physical blocks 200 marked as bad blocks by the memory controller 110, the physical blocks 200 storing system data, or the virtual bad blocks configured by the memory controller 110.

An implementation of the present disclosure takes plane_cnt=6, BLK_shift=7, and block_cnt=16 as an example to illustrate the first mapping function.

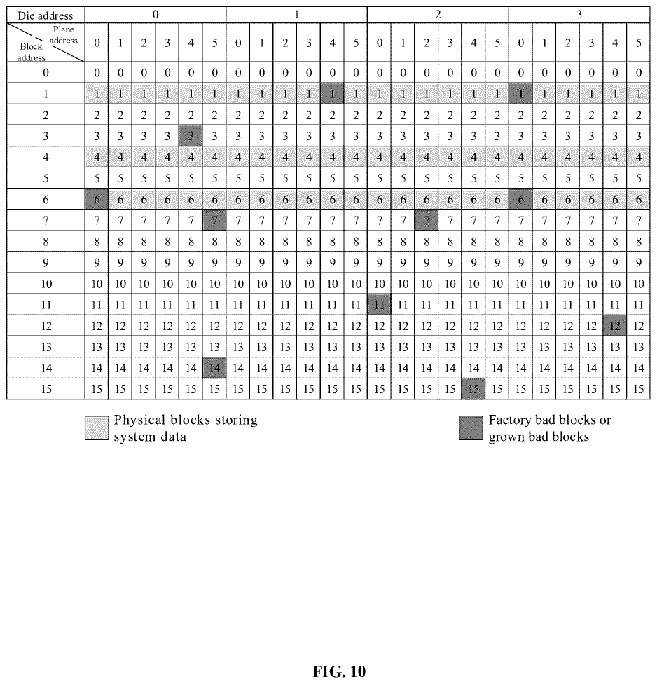

As shown in FIG. 10, the memory device 120 includes 4 dies, each die including 6 planes, and each plane including 16 physical blocks 200. Thus, super physical blocks SPB0 to SPB15 may be constituted, and each super physical block includes 24 physical blocks 200 with the same block address, wherein the super physical blocks SPB1, SPB4, and SPB6 may be physical blocks 200 for storing system data, that is to say, physical blocks 200 with block address 1, block address 4, and block address 6 are bad blocks. The memory device 120 may also include some factory bad blocks or grown bad blocks distributed randomly.

The super physical block SPB0 includes 24 physical blocks 200 with the same block address (n_block=0). When the memory controller 110 determines the super physical block SPB0 in response to the first write request, the memory controller 110 may determine the physical addresses of the first physical blocks and the second physical blocks based on the first mapping function and the physical addresses of 24 physical blocks 200 in the super physical block SPB0. The sum of a number of the first physical blocks and a number of the second physical blocks is 24.

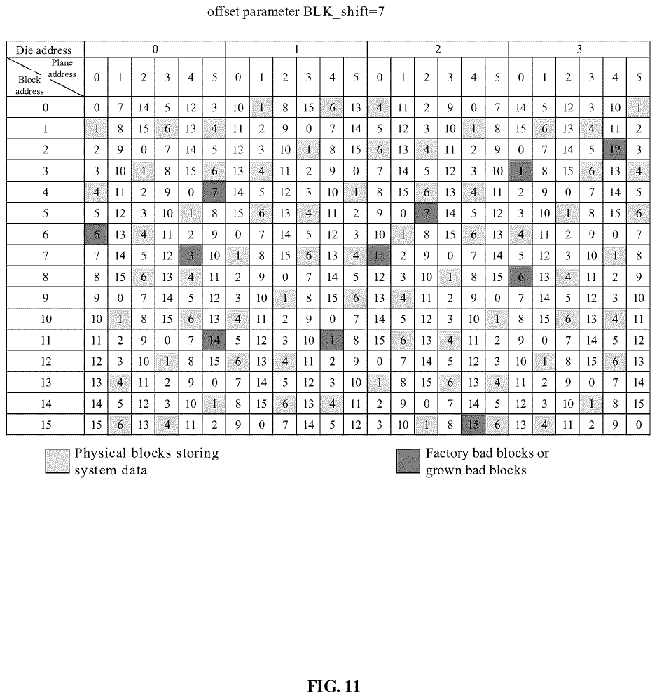

As shown in FIGS. 10 and 11, for example, in the super physical block SPB0, a physical block 200 with a die address of 0, a plane address of 0, and a block address of 0 in the physical address (e.g., a fourth physical block) may be mapped, by the first mapping function, to a physical block 200 with a die address of 0 (N_die=n_die), a plane address of 0 (N_plane=n_plane), and a block address of 0 (N_block=(0+ (0×6+0)×7)% 16=0) in the physical address (e.g., a first physical block). The physical address of the fourth physical block may be the same as the physical address of the first physical block.

As shown in FIGS. 10 and 11, for example, in the super physical block SPB0, a physical block 200 with a die address of 0, a plane address of 1, and a block address of 0 in the physical address (e.g., the fourth physical block) may be mapped, by the first mapping function, to a physical block 200 with a die address of 0 (N_die=n_die), a plane address of 1 (N_plane=n_plane), and a block address of 7 (N_block=(0+ (0×6+1)×7)% 16=7) in the physical address (e.g., the first physical block). The die address in the physical address of the fourth physical block is the same as the die address in the physical address of the first physical block, the plane address in the physical address of the fourth physical block is the same as the plane address in the physical address of the first physical block, and the block address in the physical address of the fourth physical block is different from the block address in the physical address of the first physical block. That is to say, the first mapping function may map a physical block 200 onto another physical block 200 on the same die and the same plane.

As shown in FIGS. 10 and 11, for example, in the super physical block SPB0, a physical block 200 with a die address of 0, a plane address of 2, and a block address of 0 in the physical address (e.g., the fourth physical block) may be mapped, by the first mapping function, to a physical block 200 with a die address of 0 (N_die=n_die), a plane address of and block 2 (N_plane=n_plane), a address of 14 (N_block=(0+ (0×6+2)×7)% 16=14) in the physical address (e.g., the first physical block). It can be seen that by the mapping of the first mapping function, at least one block address in the physical addresses of the first physical blocks is different from the block addresses in the physical addresses of other first physical blocks.

As shown in FIGS. 10 and 11, for example, in the super physical block SPB0, a physical block 200 with a die address of 1, a plane address of 1, and a block address of 0 in the physical address (e.g., the third physical block) may be mapped, by the first mapping function, to a physical block 200 with a die address of 1 (N_die=n_die), a plane address of 1 (N_plane=n_plane), and a block address of 1 (N_block=(0+ (1×6+1)×7)% 16=1) in the physical address (e.g., the second physical block). The physical block 200 with a die address of 1, a plane address of 1, and a block address of 1 in the physical address is a bad block and the first write command sent by the memory controller 110 to the memory device 120 does not include this physical address.

For other physical blocks 200 in the SPB0 super physical block, as well as the results of mapping the physical blocks 200 in other super physical blocks by the first mapping function, please refer to FIG. 11, which will not be repeated here in the present disclosure. As shown in FIG. 11, after being mapped by the first mapping function, each super physical block is mapped to a certain number of the first physical blocks (e.g., good blocks) and second physical blocks (e.g., bad blocks).

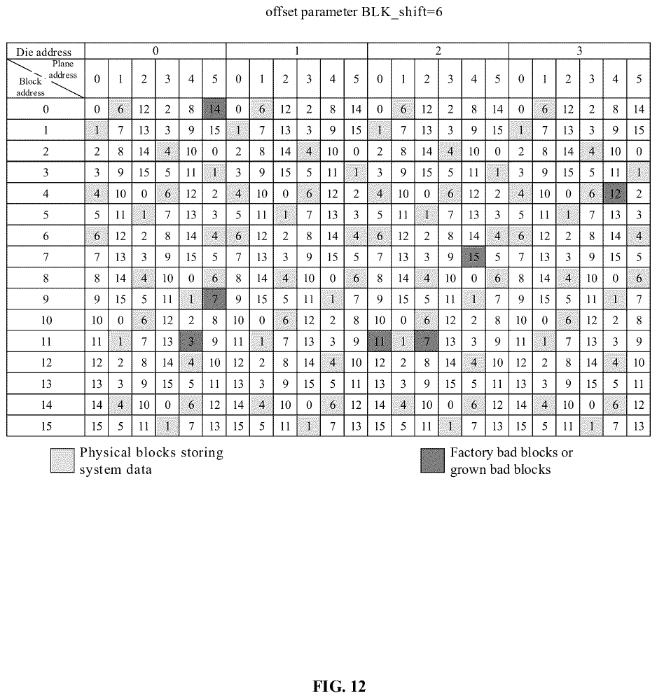

FIG. 12 shows the result after being mapped by another first mapping function with an offset parameter BLK_shift of 6. In FIG. 12, the super physical block SPB7 is mapped to 23 first physical blocks and 1 second physical block, with a relatively large number of mapped first physical blocks. The super physical block SPB4 is mapped to 15 first physical blocks and 9 second physical blocks, with a relatively small number of mapped first physical blocks. In order to control the number of the first physical blocks within a desired range, the memory controller 110 may control the number of the first physical blocks (or second physical blocks), to which each super physical block is mapped, within the desired range by adjusting the offset parameter multiple times.

An implementation of the present disclosure provides a second mapping function for implementing the mapping from the second physical blocks to the third physical blocks and from the first physical blocks to the fourth physical blocks.

The output parameters of the first mapping function include (N_die, N_plane, N_block), and the input parameters include (n_die, n_plane, n_block).

In some examples, the second mapping function includes:

$$n\_die = N\_die ;$$

$$n\_plane = N\_plane ;$$

n_block=(block_cnt×K+N_block)−(N_die×plane_cnt+N_plane)×BLK_shift;

Wherein K comprises the smallest natural number that may satisfy the value range of n_block (for example, 0-15).

An implementation of the present disclosure takes plane_cnt=6, BLK_shift=7, and block_cnt=16 as an example to illustrate the second mapping function. For example, a physical block 200 with a die address of 0, a plane address of 0, and a block address of 0 in the physical address (e.g., the first physical block) may be mapped, by the second mapping function, to a physical block 200 with a die address of 0 (n_die=N_die), a plane address of 0 (n_plane=N_plane), and a block address of 0 (n_block=(16×K+0)−(0×6+0)×7), K=0)=0, wherein K=0) in the physical address (e.g., the fourth physical block).

For example, a physical block 200 with a die address of 0, a plane address of 1, and a block address of 7 in the physical address (e.g., the first physical block) may be mapped, by the second mapping function, to a physical block 200 with a die address of 0 (n_die=N_die), a plane address of 1 (n_plane=N_plane), and a block address of 0 (n_block=(16×K+7)−(0×6+1)×7), K=0)=0, wherein K=0) in the physical address (e.g., the fourth physical block).

For example, a physical block 200 with a die address of 0, a plane address of 2, and a block address of 14 in the physical address (e.g., the first physical block) may be mapped, by the second mapping function, to a physical block 200 with a die address of 0 (n_die=N_die), a plane address of 2 (n_plane=N_plane), and a block address of 0 (n_block=(16×K+14)−(0×6+2)×7)=0, K=0) in the physical address (e.g., the fourth physical block).

For example, a physical block 200 with a die address of 1, a plane address of 1, and a block address of 1 in the physical address (e.g., the second physical block) may be mapped, by the second mapping function, to a physical block 200 with a die address of 1 (n_die=N_die), a plane address of 1 (n_plane=N_plane), and a block address of 0 (n_block=(16×K+1)−(1×6+1)×7), K=3)=0, wherein K=3) in the physical address (e.g., the third physical block).

In some implementations, the memory controller 110 may also receive a second write request and determine a super physical block in response to the second write request, and then determine the physical addresses of the fifth physical blocks based on the swap table or the first mapping function, and sends a second write command including the physical addresses of the fifth physical blocks to the memory device 120, wherein the number of the fifth physical blocks is less than the total number of the planes in multiple dies, and a difference between the number of the fifth physical blocks and the number of the first physical blocks is less than a threshold.

In some implementations, the threshold is less than or equal to 3. In some examples, the first physical blocks are determined by the super physical block SPB2 via the swap table or first mapping function, as shown in FIG. 11, and there are 18 first physical blocks. The fifth physical block is determined by the super physical block SPB9 via the swap table or first mapping function, as shown in FIG. 11, and there are 21 fifth physical blocks. The difference between the number of the fifth physical blocks and the number of the first physical blocks is equal to 3.

S200: The memory device performs a program operation on first physical blocks in response to the first write command.

As described above, the memory controller 110 determines the first physical blocks and one or more second physical blocks in response to the first write request, and sends the first write command to the memory device 120, wherein the first write command only includes the physical addresses of the first physical blocks.

Since the sum of a number of the first physical blocks and a number of the second physical blocks comprise the total number of the planes in multiple dies, the number of the first physical blocks is less than the total number of the planes in multiple dies. That is to say, when the memory controller 110 controls the memory device 120 to perform parallel data writing, the number of the physical blocks 200 for writing data each time may be smaller than the number of the physical blocks 200 included in super physical blocks, thereby reducing the amount of data written in parallel each time, significantly reducing the demand for write buffers by the memory controller 110, and reducing the demand for built-in capacitors that perform power loss protection functions, thereby reducing the design difficulty of the circuit board.

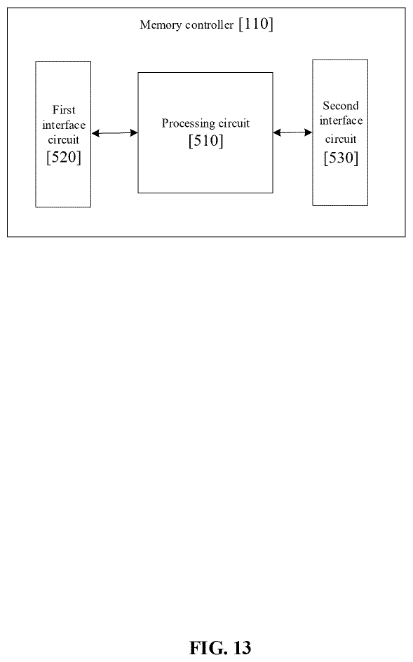

An implementation of the present disclosure further provides a memory controller 110. As shown in FIG. 13, the memory controller 110 includes a processing circuit 510, a first interface circuit 520, and a second interface circuit 530. The first interface circuit 520 and the second interface circuit 530 are respectively coupled to the processing circuit 510. The first interface circuit 520 is configured to receive a first write request, and the second interface circuit 530 is configured to couple with the memory device 120, which includes multiple dies, each die including multiple planes, each plane including multiple physical blocks 200. The processing circuit 510 is configured to receive, by the first interface circuit 520, a first write request, and send, by the second interface circuit 530, a first write command to the memory device 120 in response to the first write request, wherein the first write command includes the physical addresses of the first physical blocks, and the number of the first physical blocks is less than the total number of the planes in multiple dies.

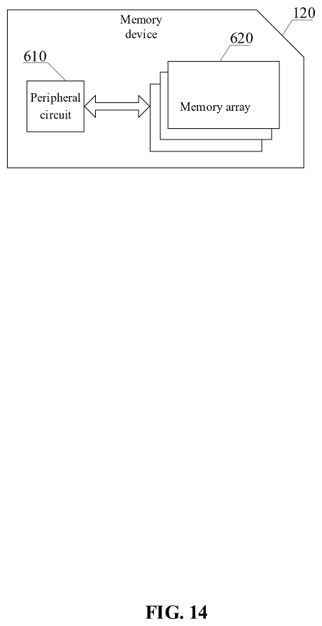

An implementation of the present disclosure provides a memory device. As shown in FIG. 14, the memory device 120 may include a memory array 620 and a peripheral circuit 610, with the memory array 620 coupled to the peripheral circuit 610. In some implementations, the peripheral circuit 610 and the memory array 620 may be independently formed on two wafers using different semiconductor process technologies. In some examples, the memory array 620 may be formed using mature manufacturing processes (such as any of 22 nm, 28 nm, and above manufacturing process) to ensure the stability of stored data. The peripheral circuit 610 may be formed using advanced manufacturing processes (such as any of 14 nm, 10 nm, and below manufacturing process), thereby facilitating to improve the speed of reading/storing data in the memory device 120. Subsequently, the wafer on which the memory array 620 is formed (referred to as array wafer) and the wafer on which the peripheral circuit 610 is formed (referred to as coms wafer) are bonded through a bonding process, thereby coupling the peripheral circuit 610 with the memory array 620.

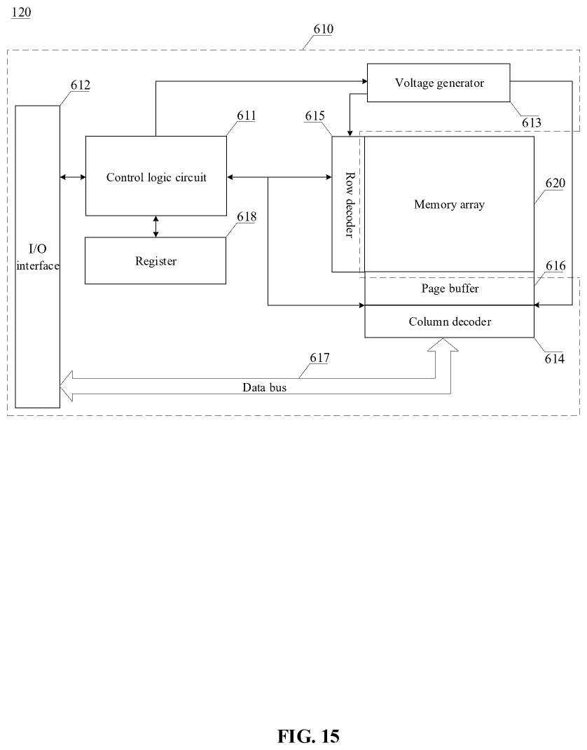

As shown in FIG. 15, in some examples, the peripheral circuit 610 includes a control logic circuit 611, an input/output (I/O) interface 612, a voltage generator 613, a column decoder 614, a row decoder 615, a page buffer 616, a data bus 617, and registers 618. It should be understood that in some examples, additional circuits not shown in FIG. 15 may also be included.

The control logic circuit 611 may be coupled to voltage generator 613, page buffer 616, column decoder 614, row decoder 615, and I/O interface 612, and configured to control operations of various peripheral circuits 610. The control logic circuit 611 may generate operation signals in response to commands (CMD) or control signals received by the I/O interface 612 to control the operations of row decoder 615, column decoder 614, page buffer 616, and voltage generator 613, wherein commands may be programming commands, read commands, etc.

The I/O interface 612 may be coupled to the control logic circuit 611 and act as a control buffer to buffer received control commands and relay them to the control logic circuit 611, and buffer received status information from the control logic circuit 611 and relay it to a host. The I/O interface 612 may also be coupled to page buffer 616 via data bus 617 and act as both a data I/O interface 612 and a data buffer to buffer data and relay it to memory array 620, relay from memory array 620 or buffer data.

The voltage generator 613 may utilize an external power supply voltage or internal power supply voltage to generate various voltages for performing operations such as erasing, programming, reading, and verifying on the memory array 620, for example, the programming voltage Vpgm, erase voltage Vera, and ground voltage VSS applied to the word line 440 and a combination thereof.

The column decoder 614 may select one or more memory strings 210 in the memory array 620 by applying the bit line 410 voltage generated from the voltage generator 613 in response to control of the control logic circuit 611.

The row decoder 615 may supply the word line 440 voltage generated from the voltage generator 613 to the selected and unselected word lines of the memory array 620 in response to control of the control logic circuit 611. As described in detail above, the row decoder 615 is configured to perform program operations on the memory cells 212 coupled to one or more selected word lines in the memory array 620.

Page buffer 616 is coupled to memory array 620 through bit line 410. In some examples, page buffer 616 may read data from memory array 620 and program (write) data to memory array 620 based on control signals from control logic circuit 611. In some other examples, page buffer 616 may store programming data (written data) to be programmed into memory array 620. In yet some examples, the page buffer 616 may also perform program validation operations to ensure that data has been correctly programmed into the memory cell 212 coupled to the selected word line.

Register 618 may be coupled to control logic circuit 611 and includes a status register, a command register, and an address register for storing status information, command opcodes (OP codes), and command addresses configured to control operations of each peripheral circuit 610.

Those skilled in the art should understand that the operations performed by the row decoder 615, page buffer 616, control logic circuit 611, and voltage generator 613 described in the present disclosure may be executed by the processing circuit, wherein the processing circuit may include but is not limited to hardware of logic circuits or hardware/software combinations of processors that execute software.

In some implementations, memory array 620 includes multiple dies, each die including multiple planes, each plane including multiple physical blocks. The memory device 120 is configured to couple with the memory controller 110, and the peripheral circuit 610 in the memory device 120 may receive a first write command sent by the memory controller 110. The first write command includes the physical addresses of the first physical blocks, and the number of the first physical blocks is less than the total number of the planes in multiple dies. The peripheral circuit 610 may also perform program operations on the first physical blocks by applying various programming voltages to the first physical blocks in response to the first write command.

An example of the present disclosure provides a computer-readable storage medium that stores computer executable instructions that, when executed, may implement any of the methods shown in FIG. 6 and FIGS. 8-12.

An example of the present disclosure provides a computer device comprising a processor and a readable storage medium coupled to the processor, wherein the readable storage medium stores executable instructions that, when executed by the processor, may implement any of the methods shown in FIG. 6 and FIGS. 8-12.

An example of the present disclosure provides a memory system, an operation method of the memory system, a memory controller, and a memory device. When the memory system 100 performs parallel data writing, the first write command sent by the memory controller 110 to the memory device 120 includes the physical addresses of the first physical blocks to control the memory device to perform program operations on the first physical block, wherein the number of the first physical blocks is less than the total number of the planes in multiple dies. As a result, the amount of data written in parallel by the memory system 100 each time is reduced, so that the requirement for write buffers by the memory controller 110 is significantly reduced, and the demand for built-in capacitors configured to perform power loss protection functions is reduced, thereby reducing the design difficulty of the circuit board.

Those skilled in the art may clearly understand that, for the convenience and conciseness of description, each example has its own emphasis in the above examples. Parts that are not detailed in a certain example will not be repeated here, and reference may be made to the corresponding process in the previous method examples.

In the several examples provided in the present disclosure, it should be understood that the provided memory system, operation method of the memory system, memory controller, and memory device may be implemented in other ways. For example, the division of a module is only a logical functional division, and there may be other division methods in actual implementations, such as multiple units or components may be combined or integrated into another system, or some features may be ignored or not executed.

Those skilled in the art may realize that the modules and algorithm operations of the examples described in connection with the examples disclosed herein may be implemented as electronic hardware, or a combination of computer software and electronic hardware. Whether these functions are executed in hardware or software depends on the specific application and design constraints of the technical solution. Professional technicians may use different methods to achieve the described functions for each specific disclosure, but such implementation should not be considered beyond the scope of the present disclosure.

In a first aspect, an example of the present disclosure provides a memory system, comprising a memory device and a memory controller, and the memory device is coupled to the memory controller. The memory device comprises multiple dies, each of the dies comprises multiple planes, and each of the planes comprises multiple physical blocks. The memory controller is configured to: receive a first write request; and send a first write command to the memory device in response to the first write request. The first write command includes physical addresses of first physical blocks, and a number of the first physical blocks is less than a total number of the planes in the multiple dies. The memory device is configured to perform a program operation on the first physical blocks in response to the first write command.

In some implementations, each of the dies comprises a same number of planes, and the number of the first physical blocks is less than a product of a number of the multiple dies and the number of the multiple planes.

In some implementations, the memory controller is further configured to: determine the first physical blocks and one or more second physical blocks in response to the first write request, wherein a sum of the number of the first physical blocks and a number of the second physical blocks comprise the total number of the planes in the multiple dies.

In some implementations, the second physical blocks comprise bad blocks.

In some implementations, the bad blocks comprise physical blocks marked as bad blocks by the memory controller.

In some implementations, physical blocks storing system data serve as the bad blocks.

In some implementations, the bad blocks comprise virtual bad blocks configured by the memory controller.

In some implementations, a number of the virtual bad blocks is determined based on a number of the multiple physical blocks included in each plane and a virtual bad block ratio.

In some implementations, the memory controller is configured with a swap table, and the swap table comprises a mapping relationship between third physical blocks and the second physical blocks.

In some implementations, the memory controller is configured with a swap table, and the swap table comprises a mapping relationship between the third physical blocks and the second physical blocks, and a mapping relationship between a fourth physical block and the first physical block. A block address in the physical address of any of the third physical blocks is the same as a block address in the physical address of any of the fourth physical blocks.

In some implementations, the memory controller is configured to: determine physical addresses of the second physical blocks based on a number of planes in a single die, the total number of the planes in the multiple dies, and physical addresses of the third physical blocks and an offset parameter; and determine physical addresses of the first physical blocks based on the number of planes in a single die, the total number of the planes in the multiple dies, and physical addresses of the fourth physical blocks and an offset parameter. A block address in the physical address of any of the third physical blocks is the same as a block address in the physical address of any of the fourth physical blocks.

In some implementations, the memory controller is configured to control the number of the first physical blocks within a desired range by adjusting the offset parameter.

In some implementations, the memory controller is further configured to: receive a second write request; and send a second write command to the memory device in response to the second write request. The second write command includes physical addresses of fifth physical blocks, a number of the fifth physical blocks is less than the total number of the planes in the multiple dies, and a difference between the number of the fifth physical blocks and the number of the first physical blocks is less than a threshold.

In some implementations, the threshold is less than or equal to 3.

In some implementations, a block address in the physical address of at least one first physical block is different from block addresses in the physical addresses of others of the first physical blocks.

In some implementations, block addresses in the physical addresses of the first physical blocks are the same.

In a second aspect, an example of the present disclosure provides an operation method of a memory system, comprising: the memory controller receives a first write request, and sends a first write command to a memory device in response to the first write request, wherein the memory device includes multiple dies, each of the dies comprises multiple planes, each of the planes includes multiple physical blocks. The first write command includes physical addresses of first physical blocks, and a number of the first physical blocks is less than a total number of the planes in the multiple dies. The memory device performs a program operation on the first physical blocks in response to the first write command.

In some implementations, each of the dies comprises a same number of planes, and the number of the first physical blocks is less than a product of a number of the multiple dies and the number of the multiple planes.

In some implementations, the operation method further comprises: the memory control determines the first physical blocks and one or more second physical blocks in response to the first write request, wherein a sum of a number of the first physical blocks and the number of the second physical blocks comprise the total number of the planes in the multiple dies.

In some implementations, the second physical blocks comprise bad blocks.

In some implementations, the bad blocks comprise physical blocks marked as bad blocks by the memory controller.

In some implementations, physical blocks storing system data serve as the bad blocks.

In some implementations, the bad blocks comprise virtual bad blocks configured by the memory controller.

In some implementations, a number of the virtual bad blocks is determined based on a number of the multiple physical blocks included in each plane and a virtual bad block ratio.

In some implementations, the memory controller is configured with a swap table, and the swap table comprises a mapping relationship between third physical blocks and the second physical blocks. The operation method comprises determining physical addresses of the second physical blocks based on the swap table and a physical addresses of the third physical blocks.

In some implementations, the memory controller is configured with a swap table, and the swap table comprises a mapping relationship between third physical blocks and second physical blocks, and a mapping relationship between a fourth physical block and the first physical block. The operation method comprises: determining physical addresses of the second physical blocks based on the swap table and physical addresses of the third physical blocks; and determining physical addresses of the first physical blocks based on the swap table and physical addresses of the fourth physical blocks. A block address in the physical address of any of the third physical blocks is the same as a block address in the physical address of any of the fourth physical blocks.

In some implementations, the operation method comprises: determining physical addresses of the second physical blocks based on a number of planes in a single die, the total number of the planes in the multiple dies, and physical addresses of the third physical blocks and an offset parameter; and determining physical addresses of the first physical blocks based on a number of planes in a single die, the total number of the planes in the multiple dies, and physical addresses of the fourth physical blocks and an offset parameter. A block address in the physical address of any of the third physical blocks is the same as a block address in the physical address of any of the fourth physical blocks.

In some implementations, the operation method further comprises controlling the number of the first physical blocks within a desired range by adjusting the offset parameter.

In some implementations, the operation method further comprises: the memory controller receives a second write request, and sends a second write command to the memory device in response to the second write request, wherein the second write command includes physical addresses of a fifth physical blocks. A number of the fifth physical blocks is less than the total number of the planes in the multiple dies, and a difference between the number of the fifth physical blocks and the number of the first physical blocks is less than a threshold.

In some implementations, the threshold is less than or equal to 3.

In some implementations, a block address in the physical address of at least one first physical block is different from block addresses in the physical addresses of others of the first physical blocks.

In some implementations, block addresses in the physical addresses of the first physical blocks are the same.

In a third aspect, an example of the present disclosure provides a memory controller, comprising: a processing circuit, a first interface circuit, and a second interface circuit, wherein the first interface circuit and the second interface circuit are coupled to the processing circuit, respectively. The processing circuit is configured to: receive, by the first interface circuit, a first write request; and send, by the second interface circuit, a first write command to a memory device in response to the first write request. The first write command includes physical addresses of first physical blocks, and a number of the first physical blocks is less than a total number of the planes in multiple dies of the memory device.

In a fourth aspect, an example of the present disclosure provides a memory device. The memory device comprises multiple dies, wherein each of the dies comprises multiple planes, each of the planes comprises multiple physical blocks. The memory device is configured to be coupled to a memory controller and is configured to: receive a first write command sent by the memory controller, wherein the first write command includes physical addresses of first physical blocks, and the number of the first physical blocks is less than the total number of the planes in the multiple dies; and perform a program operation on the first physical blocks in response to the first write command.

In a fifth aspect, an example of the present disclosure provides a computer-readable storage medium storing a computer-executable instruction that, when executed, can implement the method in the second aspect.

In a sixth aspect, an example of the present disclosure provides a computer device, comprising a processor and a readable storage medium coupled to the processor, wherein the readable storage medium stores an executable instruction that, when executed by the processor, can implement the method in the second aspect.

The above are only specific implementations of the present disclosure, but the scope of the present disclosure is not limited to this. Any change or replacement that may be easily thought of by those skilled in the art within the technical scope disclosed in the present disclosure should be included in the scope of the present disclosure. Therefore, the scope of the present disclosure should be based on the scope of the claims.

1. A memory system, comprising:
a memory controller; and
a memory device, wherein the memory device is coupled to the memory controller and comprises multiple dies, each of the dies comprises multiple planes, and each of the planes comprises multiple physical blocks,
the memory controller is configured to:
receive a first write request; and
send a first write command to the memory device in response to the first write request, wherein the first write command includes physical addresses of first physical blocks, and a number of the first physical blocks is less than a total number of planes in the multiple dies, and
the memory device is configured to:
perform a program operation on the first physical blocks in response to the first write command.

2. The memory system of claim 1, wherein each of the dies comprises a same number of planes, and the number of the first physical blocks is less than a product of a number of the multiple dies and a number of the multiple planes.

3. The memory system of claim 1, wherein the memory controller is further configured to:
determine the first physical blocks and one or more second physical blocks in response to the first write request, wherein a sum of the number of the first physical blocks and a number of the second physical blocks is the total number of planes in the multiple dies.

4. The memory system of claim 3, wherein the second physical blocks comprise bad blocks.

5. The memory system of claim 4, wherein the bad blocks comprise ones of the second physical blocks marked as bad blocks by the memory controller.

6. The memory system of claim 4, wherein ones of the physical blocks storing system data serve as the bad blocks.

7. The memory system of claim 4, wherein the bad blocks comprise virtual bad blocks configured by the memory controller.

8. The memory system of claim 3, wherein the memory controller is configured with a swap table, and the swap table comprises a mapping relationship between third physical blocks and the second physical blocks.

9. The memory system of claim 1, wherein a block address in the physical address of at least one of the first physical blocks is different from block addresses in the physical addresses of others of the first physical blocks.

10. The memory system of claim 1, wherein block addresses in the physical addresses of the first physical blocks are the same.

11. A method of operating a memory system, the method comprising:
receiving, by a memory controller, a first write request;
sending a first write command to a memory device in response to the first write request, wherein the memory device comprises multiple dies, each of the dies comprises multiple planes, and each of the planes comprises multiple physical blocks, and wherein the first write command includes physical addresses of first physical blocks, and a number of the first physical blocks is less than a total number of planes in the multiple dies; and
performing, by the memory device, a program operation on the first physical blocks in response to the first write command.

12. The method of claim 11, wherein each of the dies comprises a same number of planes, and the number of the first physical blocks is less than a product of the number of the multiple dies and a number of the multiple planes.

13. The method of claim 11, further comprising:
determining, by the memory controller, the first physical blocks and one or more second physical blocks in response to the first write request, wherein a sum of the number of the first physical blocks and a number of the second physical blocks is the total number of planes in the multiple dies.

14. The method of claim 13, wherein the second physical blocks comprise bad blocks.

15. The method of claim 14, wherein the bad blocks comprise ones of the second physical blocks marked as bad blocks by the memory controller.

16. The method of claim 15, wherein ones of the physical blocks storing system data serve as the bad blocks.

17. The method of claim 15, wherein the bad blocks comprise virtual bad blocks configured by the memory controller.

18. The method of claim 13, wherein the memory controller is configured with a swap table, and the swap table comprises a mapping relationship between third physical blocks and the second physical blocks, and the method comprises:
determining physical addresses of the second physical blocks based on the swap table and physical addresses of the third physical blocks.

19. The method of claim 11, further comprising:
receiving, by the memory controller, a second write request; and
sending a second write command to the memory device in response to the second write request, wherein the second write command includes physical addresses of fifth physical blocks, a number of the fifth physical blocks is less than the total number of planes in the multiple dies, and a difference between the number of the fifth physical blocks and the number of the first physical blocks is less than a threshold.

20. A memory controller, comprising:
a processing circuit;
a first interface circuit; and
a second interface circuit, wherein the first interface circuit and the second interface circuit are coupled to the processing circuit, respectively, and
the processing circuit is configured to:
receive, by the first interface circuit, a first write request; and
send, by the second interface circuit, a first write command to a memory device in response to the first write request, wherein the first write command includes physical addresses of first physical blocks, and a number of the first physical blocks is less than a total number of planes in multiple dies of the memory device.
